(19) United States
(12) Patent Application Publication
(10) Pub. No.: US 2026/0219574 A1
(43) Pub. Date: Jul. 30, 2026

(54) PHOSPHORUS-BASED FILM COMPOSITIONS AND PATTERNING METHODS

(71) Applicants: The University of Queensland, Brisbane (AU); Tokyo Electron Limited, Tokyo (JP)

(72) Inventors: Andrew Whittaker, Toowong (AU); Idriss Blakey, Mansfield (AU); Hui Peng, Toowong (AU); Josua Markus, Chapel Hill (AU); Md Daloar Hossain, St. Lucia (AU); Charlotte Cutler, Albany, NY (US); David Conklin, Saratoga Springs, NY (US)

(21) Appl. No.: 19/037,976

(22) Filed: Jan. 27, 2025

(51) Int. Cl. G03F 7/038; G03F 7/20; G03F 7/36; G03F 7/40

(52) U.S. Cl. CPC G03F 7/0384; G03F 7/2002; G03F 7/36; G03F 7/40

(57) ABSTRACT

A photoresist formulation for coating substrates includes a monomer and an organic solvent. The monomer includes an olefin and a phosphate ester.

### TECHNICAL FIELD

The present invention relates to the field of semiconductor manufacturing, and in various embodiments, to phosphorus-based compositions and methods of forming and patterning the corresponding films.

### BACKGROUND

Semiconductor devices are generally fabricated by sequentially depositing and patterning layers of materials over a substrate to form a network of electronic components (such as transistors, resistors, and capacitors) and interconnect elements (such as metal lines, contacts, and vias) that are integrated together in a monolithic structure. At each successive process node, minimum feature sizes shrink such that component packing densities roughly double and per-component costs are controlled.

The requisite patterning is typically performed using lithography, in which a thin layer of radiation-sensitive material (or resist) is applied to a substrate and exposed to actinic radiation through a mask or reticle (and associated optics). The substrate is then washed with a developer solvent that removes either the exposed or the unexposed portions of the resist, corresponding to positive or negative tone. The resulting relief pattern may be used as a mask or template for additional processing, such as transferring the pattern into an underlying material layer.

Significant advances in lithographic technology—such as immersion lithography and extreme ultraviolet (EUV) lithography—have enabled scaling of semiconductor process nodes below 10 nm, surpassing the physical limits of some technologies (such as NAND memory). As a result, planar and 3D architectures comprising features with high aspect ratio (thickness:width) are increasingly common, and their fabrication may entail the use of masks with correspondingly high aspect ratios that nevertheless exhibit high etch resistance. Innovations in resist chemistry may be sought to meet ever stricter requirements for pattern clarity, etch resistance, and other properties.

### SUMMARY

In an embodiment, a photoresist formulation for coating substrates includes a monomer and an organic solvent. The monomer includes an olefin and a phosphate ester.

In another embodiment, a photoresist formulation for coating substrates includes a polymer and an acid generator. The polymer includes a phosphate ester. The polymer and the acid generator are soluble in an organic solvent.

In still another embodiment, a method of patterning a substrate includes forming a polymer coating over a substrate by a spin-on process, the polymer coating including phosphorus; exposing the substrate to an actinic radiation through a photomask to form an exposed region and a masked region of the polymer coating, where the actinic radiation includes ultraviolet (UV) radiation; performing a first baking process on the substrate to convert the exposed region of the polymer coating into a crosslinked region of the polymer coating; rinsing the substrate with a solvent to remove portions of the masked region of the polymer coating, the removing forming a wet-developed region of the polymer coating; loading the substrate into a plasma processing chamber; and exposing the substrate to a plasma to remove the wet-developed region of the polymer coating.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1F illustrate cross-sectional views of the patterning of a substrate according to various embodiments, wherein FIG. 1A depicts a polymer coating formed over the substrate, FIG. 1B depicts exposure of the substrate to an actinic radiation through a photomask, FIG. 1C depicts conversion of an exposed region of the polymer coating to a crosslinked region by a first baking process, FIG. 1D depicts partial wet development of the polymer coating by a solvent, FIG. 1E depicts dry development of the remaining wet-developed region of the polymer coating by a plasma, and FIG. 1F depicts the resulting patterned substrate;

FIG. 2 illustrates a cross-sectional view of a substrate with a polymer coating having suffered pattern collapse;

FIGS. 3A-3C illustrates crosslinking of polymer strands comprising a phosphate ester, wherein FIG. 3A depicts an acid-catalyzed transesterification reaction between two phosphate esters to form a pyrophosphate ester linkage, FIG. 3B depicts the same process in a cartoon representation, and FIG. 3C depicts various possible inter- and intra-strand crosslinks, according to embodiments;

FIGS. 4A and 4B illustrate photoresist formulations comprising a monomer and a polymer, respectively, as well as other components that may be present in a photoresist formulation, according to various embodiments;

FIG. 5 illustrates several monomer and polymer structures for photoresist compositions comprising an olefin and a phosphate ester, including hydrocarbacrylate derivatives, according to various embodiments;

FIG. 6 illustrates several co-monomers that may be part of embodiment copolymers, according to various embodiments, and further illustrates positional numbering conventions for norbornene and styrene derivatives;

FIG. 7 illustrates derivatives of hydrocarbacrylate, norbornene, ethane, and styrene comprising open valences, the derivatives being substituted for R groups in various embodiment monomers and polymers;

FIG. 8 illustrates monomer and polymer structures for photoresist compositions comprising a styrenic unit and a phosphate ester, according to various embodiments;

FIG. 9 illustrates monomer and polymer photoresist compositions comprising a norbornenyl unit and a phosphate ester, including polymers formed by ring-opening metathesis polymerization and vinylic addition polymerization, according to various embodiments;

FIG. 10 illustrates several organic solvents that may be part of a photoresist formulation, according to embodiments;

FIGS. 11A and 11B illustrates cations and anions that may be paired to form photoacid generators that may be part of a photoresist formulation, wherein FIG. 11A depicts the cations and FIG. 11B depicts the anions, according to embodiments; and

FIG. 12 is a flow chart for a method of patterning a substrate, according to various embodiments.

### DETAILED DESCRIPTION OF ILLUSTRATIVE EMBODIMENTS

The advent of extreme ultraviolet (EUV) lithography and high-numerical aperture EUV (high-NA EUV) lithography has allowed for the fabrication of semiconductor devices comprising smallest features with characteristic width (critical dimension) below 10 nm. As such, even thin photoresist films with thicknesses of 100 nm may form patterns with an aspect ratio of 10:1 or greater. And as aspect ratios climb above 100:1 in some technologies, such as advanced memories, collapse of lithographic patterns is an ever more serious challenge for photoresist materials. Photoresists may also be sought that provide high pattern contrast and etch resistance, given that high-aspect ratio patterns may be transferred to underlying material layers by relatively lengthy etching processes.

A common photoresist chemistry for EUV applications is based on organotin oxides, which may be deposited on a substrate from the gas phase, crosslinked into networks by EUV exposure, and subsequently developed. Some organotin resists in common use can be developed without a solvent, e.g., by etching with plasma. Because no wet development or drying is required, and no capillary tension from solvent or drying-process chemicals is exerted on etched channels, the risk of pattern collapse is mitigated.

Because organotin resists (and other organometallic resists) may be effective when coated in thinner layers relative to conventional organic resists, some such resists may instead be wet-developed. Specifically, the lower aspect ratio associated with thinner features (for a given critical dimension) and the mechanical strength of organometallics may still have the combined effect of suppressing pattern collapse.

In addition to their usefulness for patterning high-aspect ratio features, organometallic resist materials meet industry specifications for pattern contrast and etch resistance. But the toxicity of some such materials (such as organotins), day-to-day variability in resist properties and stability, and the difficulty of removing residual metal from front-end-of-the-line manufacturing tracks and tools continue to spur interest in other photoresist chemistries.

Embodiments of the present disclosure enable the formation of polymer coatings comprising phosphorus (e.g., photoresist films) and patterning of substrates with high contrast and high etch resistance that do not comprise tin or other metals. Embodiment coatings may be formed by spin-on processes, rather than by deposition, and may be developed by wet, dry, or hybrid methods, as may be appropriate for mitigating pattern collapse. Embodiments achieve these advantages by leveraging phosphorus chemistry not previously used for photoresists, such as (in various embodiments) the crosslinking chemistry of phosphate esters.

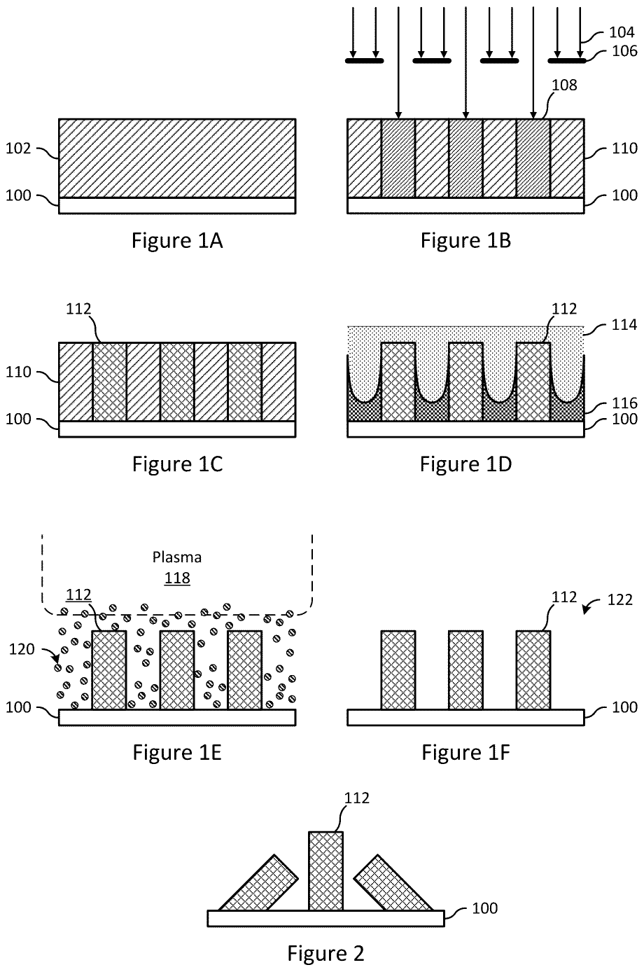

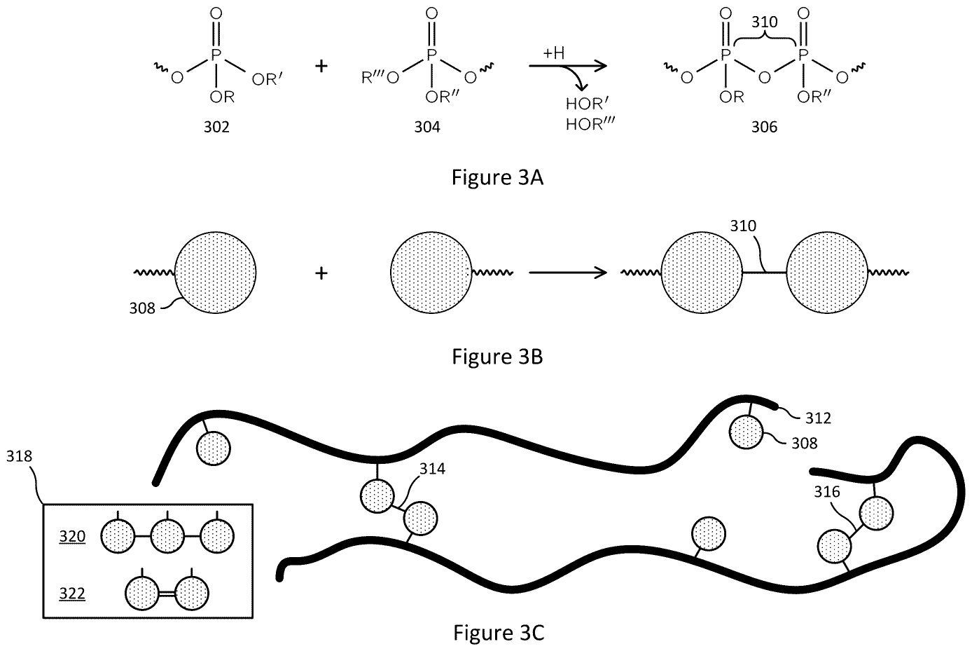

In the detailed description that follows, embodiments will be described first with reference to a process flow for patterning a polymer coating and performing a hybrid develop that may mitigate the risk of pattern collapse, as illustrated in FIGS. 1A-1F and FIG. 2. Phosphate ester crosslinking chemistry used in various embodiments to enable such a process flow will then be described with reference to FIGS. 3A-3C.

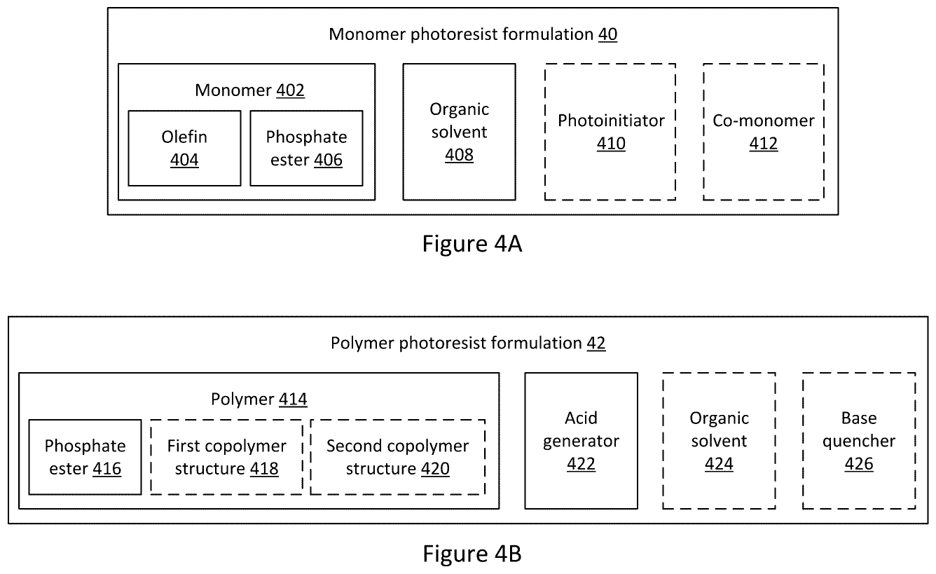

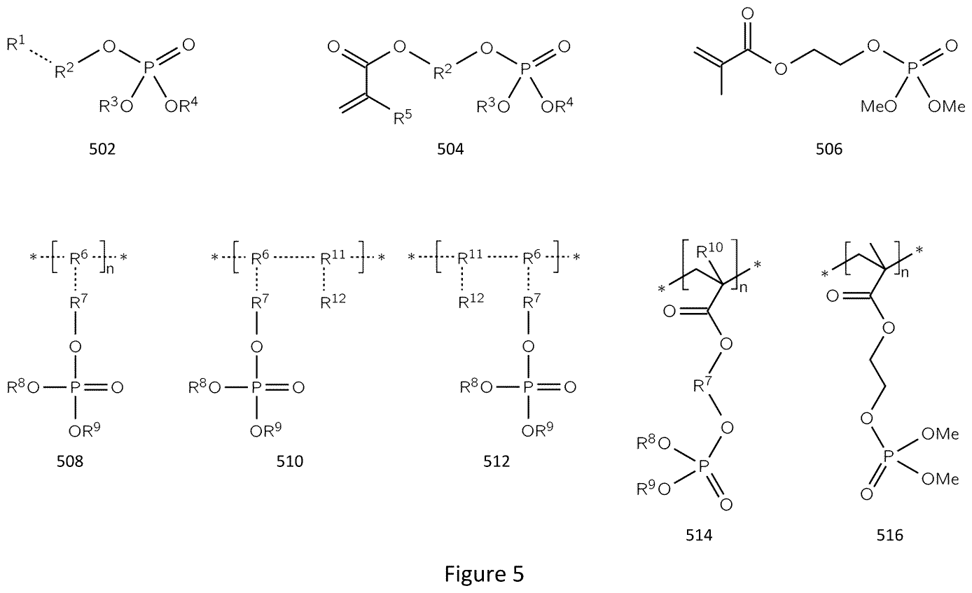

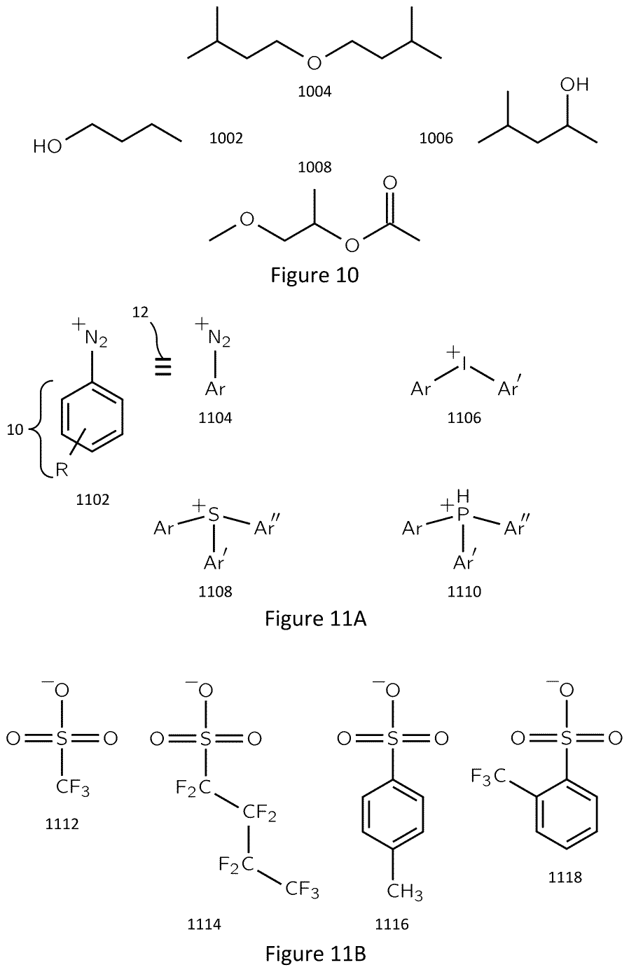

Photoresist formulations comprising a monomer or a polymer, respectively, will be described with reference to FIGS. 4A and 4B and also to FIGS. 5-9, which illustrate monomer and polymer structures consistent with embodiments of this disclosure, as well as co-monomers and other structural units that may form or be part of an embodiment polymer, according to various embodiments. Advantageous properties of embodiments will be described with reference to a specific polymer, poly(2-[(dimethoxyphosphoryl)oxy]ethyl methacrylate) (poly(DMMEP)). Other possible components of embodiment formulations, such as solvents and photoacid generators, will then be described, with reference to FIGS. 10 and 11A/11B (respectively).

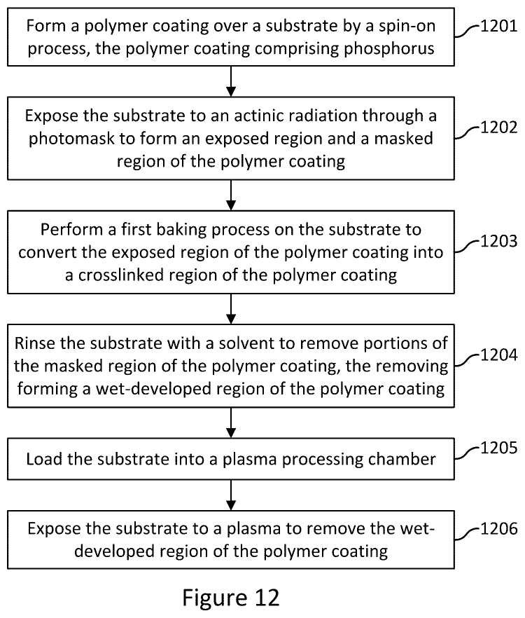

To conclude the detailed description, a more general method of patterning a substrate will be described with reference to a flow chart presented in FIG. 12.

FIG. 1A illustrates a substrate 100 with a polymer coating 102 formed over it. The substrate 100 represents generically any suitable semiconductor substrate being processed in accordance with embodiments. The substrate 100 may be a bulk substrate such as a semiconductor wafer, a semiconductor-on-insulator (SOI) wafer, or any of various other semiconductor substrates. The substrate 100 may be coated or layered with any number of additional materials and may include any material portion or structure of a device, particularly a semiconductor or other electronics device. Similarly, in some embodiments, the substrate 100 may itself be patterned or embedded in other components of a semiconductor structure or device, such as a reconstituted wafer in a wafer-level package process.

In various embodiments, the polymer coating 102 may be formed by a spin-on process such as spin coating. In some embodiments, other coating methods may be selected, such as spray coating, thermal spray coating, flow coating, dip coating, or roll coating.

In embodiments comprising spin coating, a photoresist formulation comprising or dissolved in an organic solvent (i.e., a photoresist solution) may be dispensed from a nozzle to a central portion of the substrate 100.

The photoresist solution may be dispensed while the substrate 100 is stationary (spun around its central axis (dynamic dispense) or while stationary (static dispense). The wafer may be spun at a rate (in rotations per minute, RPM) between 500 RPM and 4000 RPM to exert a centrifugal force, causing the photoresist solution to spread outward toward the edge of the substrate 100. As solvent evaporates from the photoresist solution, the polymer coating 102 may form over the substrate 100. In various embodiments, the polymer coating 102 may have a thickness between 10 nm and 10 μm. In some embodiments, the polymer coating 102 may have a thickness between 10 nm and 60 nm; in other embodiments, the polymer coating 102 may have a thickness between 70 nm and 150 nm.

Process conditions for the spin coating may comprise spin speed, spin time, substrate temperature, and the like. In certain embodiments, after spin coating, non-uniform features at the edge of the polymer coating 102 (edge bead) may be removed. Removal of edge beading may comprise dispensing solvent locally to the edge of the substrate 100 while spinning.

FIG. 1B depicts exposure of the substrate to an actinic radiation 104 through a photomask 106 in order to transfer a pattern from the photomask 106 to the polymer coating 102. The exposure forms an exposed region 108 and a masked region 110 of the polymer coating 102. According to various embodiments, the exposed region 108 may have a critical dimension between 20 nm and 400 nm.

The masked region 110 may be removed to form spaces within the exposed region 108, as described below. While a pitch of the corresponding patterning (as implied by a ratio between the widths of the exposed region 108 and the masked region 110) is 1:1 as illustrated, various embodiments may comprise line/space (L/S) patterning with pitch between 1:1 (relatively dense features) and 1:8 (relatively isolated features). In some embodiments, a desired L/S pitch may be achieved through a combination of the exposure step of FIG. 1B and a subsequent trimming process. In certain embodiments, trimming may be performed on a patterned substrate resulting from the hybrid develop described herein, such as the patterned substrate illustrated in FIG. 1F.

In various embodiments, the actinic radiation 104 may comprise ultraviolet (UV) radiation, such as h-line radiation (405 nm near UV), i-line radiation (365 nm UV), 284 nm deep UV, 193 nm deep UV, or 13.5 nm EUV. In embodiments comprising EUV, the actinic radiation 104 may be generated and delivered by an EUV lithography tool or a high numerical aperture EUV lithography tool. In these embodiments, a minimum critical dimension of the exposed region 108 may be between 1 nm and 10 nm. In some embodiments comprising a polymer coating 102 configured to absorb longer-wavelength light, the actinic radiation 104 may comprise visible light such as g-line radiation (436 nm violet light).

In other embodiments comprising patterning without the photomask 106, the actinic radiation 104 may comprise even longer wavelengths, such as red or infrared light. Some such embodiments may comprise patterning by direct laser writing. In still other embodiments not comprising a photomask 106, the actinic radiation 104 may be an electron beam comprising electrons with energy between 100 eV and 150 keV.

With further reference to FIG. 1B, and in some embodiments, the actinic radiation 104 may trigger hydrolysis of phosphate esters (with a structure such as phosphate ester 302 illustrated in FIG. 3A) in the exposed region 108 that may subsequently crosslink through a transesterification reaction, as described below with reference to FIGS. 3A-3C. In other embodiments, the actinic radiation 104 may instead trigger a photoacid generator (PAG) that releases protons capable of catalyzing the transesterification reaction. In some embodiments, transesterification reactions may occur in a nearly quantitative ratio (~1:1) to the number of protons generated, such that the photospeed of the polymer coating 102 may be limited by the properties of the photoacid generator.

In other embodiments, the photoresist solution comprise a thermal acid generator (TAG). In certain embodiments, a polymer coating 102 formed from a photoresist solution comprising a TAG may be patterned by a maskless technique such as direct laser writing. In these embodiments, heat generated within the polymer coating 102 by the write laser may trigger release of protons to catalyze crosslinking reactions, such as the phosphate transesterification illustrated in FIG. 3A.

Embodiment solutions comprising a TAG may also enable formation of a protective layer over a substrate 100. The protective layer may be formed, in various embodiments, by skipping the exposure step of FIG. 1B or by performing a flood exposure to actinic radiation 104 in the absence of the photomask 106 to stimulate phosphate ester hydrolysis. A baking process, such as that described directly below with reference to FIG. 1C, may then be performed to trigger the TAG to release protons. The protons thus produced may diffuse throughout the entirety of the polymer coating 102 to promote uniform crosslinking by catalyzing transesterification.

FIG. 1C illustrates the result of a baking process performed on the substrate 100 after the patterning of FIG. 1B. In embodiments comprising a photoresist solution with a photoacid generator, baking promotes diffusion of protons released by the PAG within the exposed region 108 of the polymer coating 102, such that crosslinking may occur to convert the exposed region 108 into a crosslinked region 112 of the polymer coating 102. In other embodiments not comprising an acid generator, a nominal amount of crosslinking may still occur subsequent to irradiation with EUV photons.

Fabrication tools for coating and developing substrates typically include one or more baking modules. In various embodiments, a baking module may comprise a hot plate, an oven, a furnace, or the like. Control parameters for the baking may comprise a bake temperature and a bake time. According to various embodiments compatible with throughput requirements for semiconductor manufacturing, the baking process may be performed for a period of 5 min or less. In some embodiments, the baking process may be performed at a temperature between 100° C. and 200° C. for a period between 30 s and 2 min.

FIG. 1D illustrates a wet develop of the masked region 110 of the polymer coating 102 using a solvent 114. In various embodiments, the develop may be performed by rinsing the substrate 100 with the solvent 114. Rinsing may comprise spraying or pulsing the solvent 114 from a nozzle disposed over the substrate 100, flowing the solvent 114 over the substrate 100, or dipping the substrate 100 into a sufficient volume of the solvent 114 to cover it. In some embodiments, the solvent 114 may be the same as the organic solvent of the photoresist solution used to form the polymer coating 102. In other embodiments, the solvent 114 may be a different solvent configured to dissolve the masked region 110 selectively.

According to various embodiments, the wet develop may be timed to preserve a portion of the masked region 110, thereby forming a wet-developed region 116 of the polymer coating 102. In various embodiments, the wet develop may be performed for a period between 5 s and 5 min. Though not as illustrated, some embodiments may further comprise a second baking process to assist in driving off excess solvent from the substrate 100. Other embodiments may comprise a different drying process, such as drying under pressure with supercritical carbon dioxide.

While the aspect ratio of the crosslinked region 112 illustrated in FIGS. 1C-1F is rather modest (roughly 7:3), various embodiments may comprise features with high aspect ratio, such as 20:1, 100:1, or even higher. A partial wet develop like that illustrated in FIG. 1D may help to ensure that the wet-developed region 116 is sufficiently thick to support a lower portion of the crosslinked region 112 during baking or drying. In various embodiments, the wet-developed region may have a thickness between 0% and 50% of the total thickness of the polymer coating 102.

Because the lower portion of the crosslinked region 112 may be surrounded by the wet-developed region 116, the crosslinked region 112 may have an effective aspect ratio lower than that defined by its total thickness and critical dimension. Without committing to any particular theory, capillary forces exerted on the crosslinked region 112 during baking or drying after the partial wet develop may therefore be less likely to damage or collapse the nascent pattern. By contrast, a high-aspect ratio pattern developed entirely by a wet develop process may be susceptible to pattern collapse, as illustrated in FIG. 2.

In other embodiments (though not as illustrated), a partial wet develop may principally remove central portions of the masked region 110 of the polymer coating 102, such that portions of the wet-developed region 116 adjacent to the masked region 110 may have a thickness over the substrate 100 comparable to that of the masked region 110. In such embodiments, the masked region 110 and the wet-developed region 116 define a compound feature with a larger critical dimension than the masked region 110 itself. This compound feature may therefore have a lower aspect ratio (and less susceptibility to pattern collapse) than the masked region 110 would on its own.

According to embodiments, and with further reference to FIG. 1E, the partially patterned and developed substrate 100 may then be loaded into a plasma processing chamber for a dry develop that removes the wet-developed region 116. The dry develop may be performed using any suitable plasma etching method (such as reactive ion etching).

The plasma processing chamber (not illustrated) may be part of a single-wafer plasma apparatus or part of a batch unit comprising two or more substrate holders or stations, according to various embodiments. The apparatus may generate a plasma 118 by any suitable means, such as inductive or capacitive coupling to radiofrequency or microwave radiation; electron cyclotron resonance; or a helical resonator configured to produce helicons, according to various embodiments.

The plasma 118 may comprise an etch gas such as elemental oxygen (O₂), carbon tetrafluoride (CF₄), elemental hydrogen (H₂), or other gases, in various combinations and admixtures thereof. Plasma particles 120 (such as ions or neutral radicals formed from the etch gas) may bombard the surface to sputter the wet-developed region 116 of the polymer coating 102, or to form volatile products by reaction with it. In some embodiments, hydrogen-rich chemistries may facilitate formation of phosphine molecules (PH₃) that may adsorb to and passivate sidewalls of the crosslinked region 112.

In some embodiments, the substrate 100 may be cooled by conventional refrigeration, cryogenic chilling, or both. In these embodiments, the cooling may be performed before and during etching—to promote retention of passivating molecules on sidewalls of the crosslinked region 112, for example—or afterward. In other embodiments, the substrate 100 may be heated before, during, or after etching—for example, to drive off adsorbed species after etching is complete. In still other embodiments, the substrate 100 may be variously cooled and heated before, during, or after etching, according to any suitable protocol.

FIG. 1F depicts an outgoing patterned substrate 122 that may be obtained by the process flow illustrated in the preceding figures. According to various embodiments, the patterned substrate 122 may be processed further using various semiconductor manufacturing techniques, such as etching of the substrate 100 or a material layer within it, deposition of an additional mask material over the crosslinked regions 112, surface decoration of the crosslinked regions 112 with ions or charged molecules followed by area-selective deposition, and so on.

According to various embodiments of the present disclosure, advantageous crosslinking and etching properties may be achieved by leveraging the chemistry of phosphorus in the polymer coating 102. For example, FIGS. 3A-3C illustrate crosslinking of polymer strands 312 comprising a phosphate ester 302 or 304, wherein R, R′, and higher primed R groups may be hydrocarbyl groups (groups with a single open valence obtained by removing a hydrogen atom from a hydrocarbon).

In other embodiments, different phosphorus-containing functional groups may be part of the polymer coating 102, whether in addition to or as an alternative to a phosphate ester. Suitable phosphorus-containing functional groups may comprise phosphorus-carbon bonds (such as in phosphines, bisphosphonates, or phosphonium cations), phosphorus-nitrogen bonds (such as in phosphonamidates), phosphorus-oxygen bonds (such as in phosphites or phosphine oxides), phosphorus-sulfur bonds (such as in thiophosphates), or phosphorus-fluorine bonds (such as in phosphofluoridates), according to various embodiments.

FIG. 3A presents a prototypical phosphate transesterification reaction between a pair of phosphate esters 302 and 304. The wavy bond to an oxygen of each phosphate ester indicates bonding to a generic molecule, such as monomer or a polymer, according to various embodiments. The pair of phosphate esters 302 and 304 further comprises four pendant hydrocarboxy groups (—OR, —OR′, and higher primed groups, wherein the R's are hydrocarbyl groups) that may be all different, all the same, or partially matched, in various embodiments.

Phosphate esters 302 and 304 may be hydrolyzed—whether spontaneously, by actinic radiation such as EUV, by acid catalysis, or by some other mechanism—to release two alcohol molecules (such as HOR′ and HOR′″, as illustrated in FIG. 3A) and to form a phosphoanhydride bond (P—O—P, a crosslink) 310. The product of the transesterification reaction is a pyrophosphate ester 306.

FIG. 3B cartoons the same process, showing each phosphate ester 302 and 304 as a pattern-filled ball 308 (filled identically, though in embodiments the pendant groups of the phosphate ester may vary). Pairs of pattern-filled balls 308 may be crosslinked; because the crosslink 310 in FIG. 3A and the crosslink 310 in FIG. 3B are in direct correspondence, they are numbered identically.

Given that phosphate esters may crosslink by the transesterification reaction of FIG. 3A, FIG. 3C illustrates (in cartoon form) various types of crosslinking that may be exhibited by a polymer strand 312 comprising a phosphate ester, as represented by the pattern-filled ball 308. The polymer strand 312 and its counterpart in FIG. 3C may have a variable number of phosphate esters per unit length, and may have identical or different compositions, according to various embodiments.

A pair of polymer strands may form an interstrand crosslink 314 when in proximity, and a high-molecular weight polymer network may form with even just one interstrand crosslink 314 per polymer strand (on average). An intrastrand crosslink 316 may also form within a single polymer strand 312. While such intrastrand bonds may affect mechanical and other properties of a polymer strand or a larger polymer network, they may not contribute directly to converting the exposed region 108 to a crosslinked region 112.

Inset 318 of FIG. 3C illustrates additional possible crosslinks, given that no more than two crosslinks may form per phosphate ester while retaining a bond to the polymer strand 312. A triphosphate ester crosslink 320 may form as a series linkage between three phosphate esters, as may oligophosphate (or even polyphosphate) ester crosslinks comprising four or more phosphate esters bonded in series. Double crosslinks between pairs of phosphate ester yield a metaphosphate linkage 322 (—P₂O₆—). To the extent that these multiply linked motifs comprise at least one interstrand crosslink 314, they may contribute to converting the exposed region 108 to a crosslinked region 112, according to various embodiments.

Various embodiments of the present disclosure may be photoresist formulations comprising a monomer (that may subsequently be polymerized) or a polymer. FIGS. 4A and 4B respectively illustrate a monomer photoresist formulation 40 and a polymer photoresist formulation 42, according to embodiments. Components outlined with a solid line are present in a given formulation, while those outlined with a dashed line may be present in some embodiments of that formulation.

With reference to FIG. 4A, a monomer photoresist formulation 40 comprises a monomer 402 and an organic solvent 408, e.g., a solvent configured to dissolve a polymer formed from the monomer 402. The monomer 402 comprises an olefin (a carbon-carbon double bond, C═C) and a phosphate ester (with the structure indicated in FIG. 3A), according to various embodiments.

In various embodiments, the monomer photoresist formulation 40 may further comprise a photoinitiator 410 or a co-monomer 412 (which may subsequently copolymerize with the monomer 402). In embodiments comprising either (or both) of the photoinitiator 410 and the co-monomer 412, the monomer photoresist formulation 40 may be a polymerization mixture capable of forming a photoresist solution in the sense described with reference to FIGS. 1A-1F. Subsequent to polymerization and addition of an acid generator 422 (with reference to FIG. 4B), an embodiment polymerization mixture may be converted into a corresponding embodiment polymer photoresist formulation 42. Note, however, that a given polymer photoresist formulation 42 may be prepared by any convenient method and need not be synthesized directly from a monomer photoresist formulation 40.

In various embodiments, the monomer photoresist formulation 40 may further comprise additional co-monomers with different composition from the monomer 402 and the co-monomer 412, additional solvents compatible with the organic solvent 408, small-molecule crosslinkers comprising phosphate esters, and the like.

With reference to FIG. 4B, a polymer photoresist formulation 42 comprises a polymer 414 and an acid generator 422. The polymer 414 and the acid generator 422 are soluble in an organic solvent 424 selected for the purpose. In some embodiments, the organic solvent 424 may be part of the polymer photoresist formulation 42, i.e., the formulation is a photoresist solution in the sense described with reference to FIGS. 1A-1F.

According to various embodiments, the polymer 414 comprises a phosphate ester (with the structure indicated in FIG. 3A). In embodiments comprising a polymer formed from more than one polymerizable molecule (i.e., a copolymer), the polymer photoresist formulation 42 may further comprise a first copolymer structure 418 or a second copolymer structure 420. According to various embodiments, the polymer photoresist formulation 42 may also comprise a base quencher 426.

In various other embodiments, the polymer photoresist formulation 42 may further comprise additional polymers with different composition from the polymer 414 and soluble in the organic solvent 424, additional solvents compatible with the organic solvent 424, small-molecule crosslinkers comprising phosphate esters, and the like.

An embodiment monomer photoresist formulation 40 may have at least one corresponding embodiment polymer photoresist formulation 42, depending on the underlying polymerization chemistry. Monomers may polymerize by various mechanisms, such as radical polymerization, metathesis polymerization (including ring-opening metathesis polymerization), vinylic addition, etc., according to embodiments. Polymerization of the olefin 404 of the monomer 402 by these mechanisms may produce a polymer with a hydrocarbon backbone structure.

In some embodiments, the polymer photoresist formulation 42 may comprise a polymer 414 formed from a monomer comprising a different polymerizable unit (and thus producing a different backbone structure) and a phosphate ester 416. Such embodiments may comprise polyurethanes, silicones, polythioethers, polyimides, polyethers (such as aryl ethers), epoxy resins, or other classes of polymers comprising heteroatoms such as nitrogen, oxygen, silicon, or sulfur.

Some embodiments of the polymer photoresist formulation 42 may comprise condensation polymers. Condensation polymers form by reactions between pairs of precursor molecules that do not necessarily polymerize in isolation, such that both molecules, one molecule, or neither molecule may be a monomer in the sense of also being a minimal repeat unit of the resulting polymer. In embodiments of the monomer photoresist formulation 40 configured to form a condensation polymer, the monomer 402 may be a molecule that undergoes condensation reaction with itself to form the condensation polymer; a minimal repeat unit of the condensation polymer formed by the condensation reaction between two precursor molecules; or a precursor molecule comprising a structural unit of the minimal repeat unit of the condensation polymer (such that the co-monomer 412 may be the other precursor molecule, in embodiments).

Various embodiments of the monomer photoresist formulation 40 and the polymer photoresist formulation 42 may be understood in more detail with reference to FIGS. 5-9, which illustrate monomers, co-monomers, and other structural units together with corresponding polymers and copolymer structures.

FIG. 5 illustrates several monomers comprising an olefin and a phosphate ester, according to various embodiments, as well as several polymer and copolymer structures. Here (and in other figures presenting chemical structures), stereochemistry is not indicated. All possible stereoisomers, diastereomers (including meso configurations), cis or trans conformations of double bonds, exo or endo conformations of non-planar rings, and axial or equatorial positions of non-planar ring substituents corresponding to a given monomer structure may be embodiments of the present disclosure. Similarly, any and all tacticities corresponding to a given polymer structure may be embodiments.

Each monomer in FIG. 5 corresponds to various realizations of a generic monomer structure 502, which comprises a polymerizable unit R¹ (itself comprising the olefin 404 of monomer 402), a side-chain connector R², and a phosphate ester comprising a first pendant group R³ and a second pendant unit R⁴. A dashed bond between the polymerizable unit R¹ and the side-chain connector R² may be a single bond or a double bond, according to various embodiments.

The side-chain connector R² of generic monomer structure 502 may comprise an organyl group, which may be any organic substituent group having open valences for bonding to one or more carbon atoms, according to various embodiments. An organyl group may comprise cycles, heteroatoms, multiply bonded atoms, and so on.

The first pendant group R³ and the second pendant group R⁴ of the phosphate ester of generic monomer structure 502 may respectively comprise a first hydrocarbyl group and a second hydrocarbyl group. As described above, hydrocarbyl groups may be groups with a single open valence obtained by removing a hydrogen atom from a hydrocarbon.

In some embodiments, the pendant groups R³ and R⁴ may both be methyl groups. In other embodiments, one or both pendant groups may be substituted with an ethyl group; an n-propyl or isopropyl group; an n-butyl, isobutyl, sec-butyl, or tert-butyl group; or a higher alkyl group. Substitution of one or both pendant groups in this fashion may reduce the activation energy for elimination of the corresponding alcohols and tune the sensitivity of the transesterification reaction to the presence of acid.

A generic polymer structure 508, by contrast, comprises n instances (where an integer n≥2) of some minimal repeat unit bonded to each other, with each comprising a phosphate ester. In embodiments corresponding to polymerization of the generic monomer structure 502, each polymerizable unit R¹ may be converted by bond rearrangements into a backbone unit R⁶ in generic polymer structure 508.

As before, a side-chain connector R⁷ may comprise an organyl group, and a first pendant group R⁸ and a second pendant group R⁹ of the phosphate ester may comprise respective hydrocarbyl groups. Dashed bonds to the backbone unit R⁶ may comprise separately selected single or double bonds, according to various embodiments. Stars at either side of the generic polymer structure 508 may separately indicate an end group (as may be determined by a choice of photoinitiator 410 in the monomer photoresist formulation 40) or a neighboring block of a copolymer structure, according to various embodiments.

In embodiments of the polymer photoresist formulation 42 comprising a copolymer, at least one copolymer structure bonding the minimal repeat unit of generic polymer structure 508 to a different structure may be present. The copolymer structure may be a first copolymer structure 510 or a second copolymer structure 512, which differ only in their linear arrangement within the copolymer. In some embodiments, both copolymer structures 510 and 512 may be present.

In the copolymer structures 510 and 512, a copolymer backbone unit R¹¹ is bonded to the backbone unit R⁶ and to a copolymer side-chain R¹². The copolymer backbone unit R¹¹ and the copolymer side-chain R¹² may comprise separately selected organyl groups. As before, dashed bonds to the backbone unit R⁶ or to the copolymer backbone unit R¹² comprise separately selected single or double bonds, according to various embodiments. Stars at either side of the first copolymer structure 510 and the second copolymer structure 512 may separately indicate an end group or a neighboring block of the copolymer, according to various embodiments.

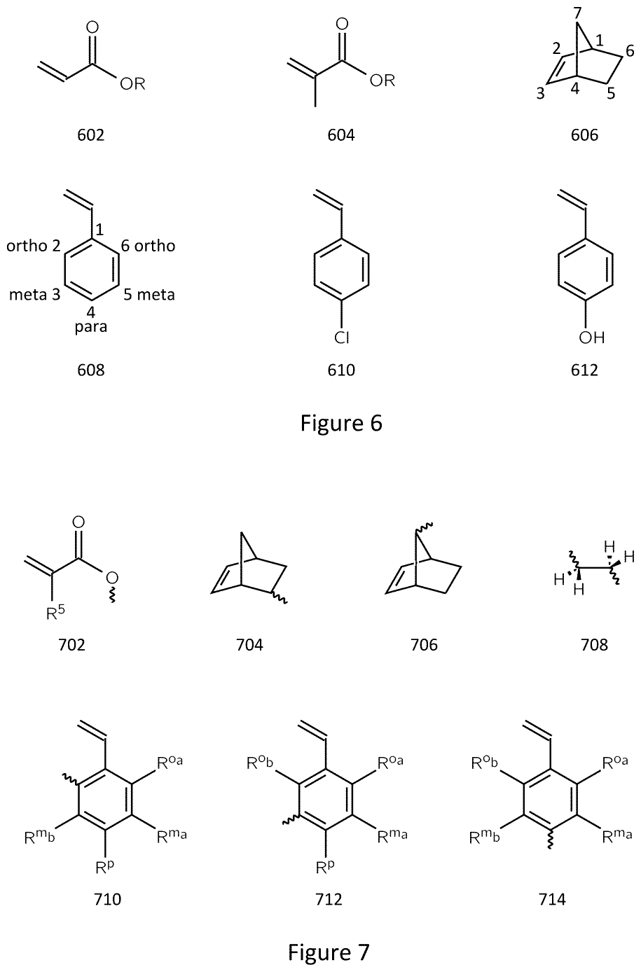

In some embodiments, and with reference to FIGS. 6 and 7, the polymerizable unit R¹ of generic monomer structure 502 may be a hydrocarbacrylate unit 702 with a pendant group R⁵ that may be a hydrocarbyl group. (The hydrocarbacrylate unit 702 may be derived from an acrylate 602, a methacrylate 604, or a generic hydrocarbacrylate by removing an R group from the ester oxygen.) A hydrocarbacrylate monomer structure 504 thus comprises a single bond to the side-chain connector R². A corresponding polymer, according to embodiments, is hydrocarbacrylate polymer structure 514, which comprises a saturated hydrocarbon backbone and a pendant group R¹⁰ that may be a hydrocarbyl group. As before, stars may separately indicate end groups or neighboring blocks of a copolymer.

In a particular embodiment of both generic monomer structure 502 and hydrocarbacrylate monomer structure 504, the polymerizable unit R¹ may be a methacrylate; the side-chain connector R² may be (with reference to FIG. 7) a 1,2-ethanediyl unit 708; and the pendant groups R³ and R⁴ may both be methyl groups (—CH₃ or -Me), yielding a monomer with systematic name 2-[(dimethoxyphosphoryl)oxy]ethyl methacrylate (DMMEP) 506. A corresponding polymer structure is poly(DMMEP) 516.

Embodiments comprising poly(DMMEP) 516 enable advantageous crosslinking, as exemplified by the inventors' contrast tests. In these tests, the inventors coated films comprising poly(DMMEP) 516 (initially dissolved in 1-butanol) over a substrate to a thickness of about 100 nm. They then exposed the films to an EUV source with power density of about 0.1 mW/cm² for varying lengths of time before baking for 60 s at either 130° C. or 180° C. The films were then developed in 1-butanol for 60 s, and the thickness of the films was remeasured.

The inventors observed that films comprising poly(DMMEP) 516 and a photoacid generator retained their thickness nearly quantitatively after about 50-100 s of exposure (about 5-10 mJ/cm² of energy delivered), irrespective of the bake temperature. The inventors further observed that films comprising poly(DMMEP) 516 without the acid generator 422 (serving as a proxy for the masked region 110 of FIG. 1B) are fully developable after 50-100 s of exposure, such that these films provide a high-contrast resist.

Even so, in some embodiments, films of poly(DMMEP) 516 not comprising the acid generator 422 may still achieve significant crosslinking, such that 50% or more of the initial film thickness is retained. Longer photoexposures (or modified baking conditions) may be needed, however. For example, the inventors observed that films prepared without the acid generator 422 and baked at 130° C. required over 12 min of exposure to exceed 50% retention. With a 180° C. bake, such films still required over 6 min of exposure to retain more than 50% of their initial thickness.

Embodiments comprising poly(DMMEP) 516 also enable advantageous etch rates in an oxygen plasma, at or below a rule-of-thumb threshold of about 0.4 nm/s for an etch-selective material. As a basis for comparison, conventional organic photoresists such as poly(methyl methacrylate), poly(adamantyl methacrylate), and polystyrene have etch rates in oxygen plasma of about 0.92 nm/s, 0.69 nm/s, and 0.47 nm/s, respectively. The inventors have observed that films comprising poly(DMMEP) 516 have an etch rate of about 0.23 nm/s under comparable conditions, slower by a factor of 2-4 relative to the conventional resists. Films formed by copolymerization of DMMEP 506 with styrene 608 (e.g., 40 mol %: 60 mol %) have nearly as low an etch rate, about 0.29 nm/s, indicating that copolymerization may enable tuning of mechanical or chemical properties of the poly(DMMEP) 516 (such as the glass transition temperature) without suppressing its advantageous etching properties.

In embodiments with a polymer comprising a phosphate ester, an etch-stop barrier may form after a period of exposure to the oxygen plasma. For example, the inventors observed that poly(DMMEP) 516 forms such a barrier after about 100 s of exposure. Inventors' X-ray photoelectron spectroscopy measurements suggest that the etch-stop barrier may be an oxygen-impermeable polyphosphate layer. In some embodiments, an etch-stop barrier formed from embodiment polymers may advantageously function as a hard mask for an underlying material layer.

More generally, polymer coatings comprising phosphorus in functional groups other than a phosphate ester may also enable advantageous etch resistance. For example, poly(triethyl(4-vinylbenzyl)phosphonium chloride), or poly(TEP), is a charged polymer comprising a triethylphosphonium (Et₃P⁺—) side chain attached to a styrene-derived polymer backbone. The inventors have observed the poly(TEP) has an etch rate of about 0.39 nm/s in oxygen plasma, which (like poly(DMMEP) 516) is superior to poly(methyl methacrylate), poly(adamantyl methacrylate), and polystyrene.

Larger or more symmetric polymerizable units than the hydrocarbacrylate unit 702 may comprise several sites well-separated from the olefin 404, each of which may be bonded to the side-chain connector R² in a given realization of the generic monomer structure 502. Two such polymerizable units are norbornene 606 and styrene 608, each of which is illustrated in FIG. 6 together with a corresponding positional numbering convention.

For styrene 608, positional numbering on the benzene ring begins at 1 (the carbon with the vinyl group) and may increase counterclockwise. The 2^{nd}/6^{th}, 3^{rd}/5^{th}, and 4^{th} positions are respectively (and equivalently) referred to as ortho, meta, and para positions.

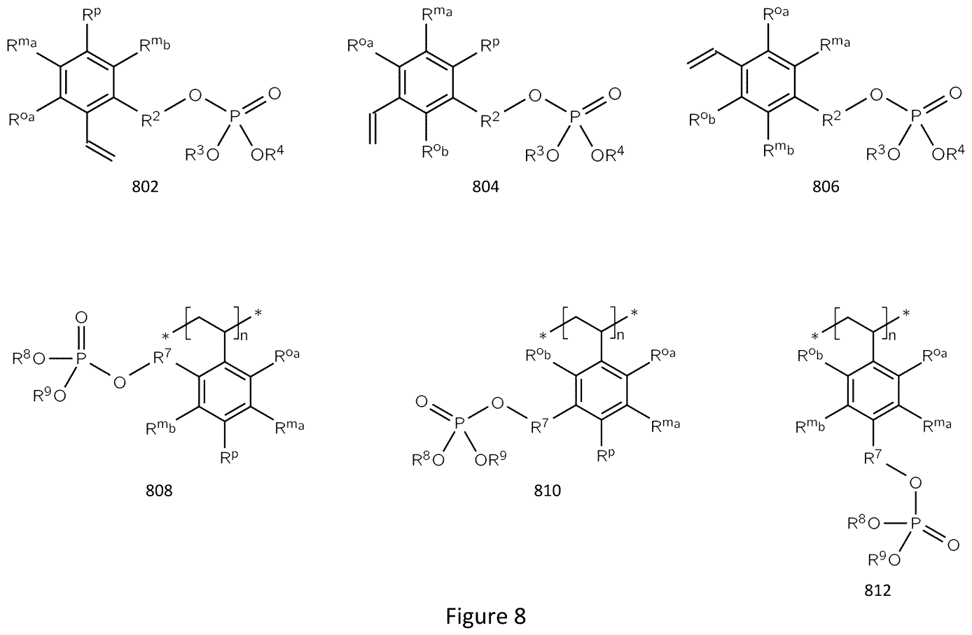

Embodiments of the generic monomer structure 502 may comprise styrene-based monomers obtained (with reference to FIG. 7) by selecting the polymerizable unit R¹ to be derived from an ortho-styrenic unit 710, a meta-styrenic unit 712, or a para-styrenic unit 714. The resulting ortho-, meta-, and para-styrenic monomers 802, 804, and 806 and corresponding ortho-, meta-, and para-styrenic polymers 808, 810, and 812 are illustrated in FIG. 8. These embodiments comprise respective combinations of one or two ortho substituents (labeled R^{o}^{ₐ} and R^{o}^{_{b}}), one or two meta substituents (labeled R^{m}^{ₐ} and R^{m}^{_{b}}), and zero or one para substituent (R^{p}). In various such embodiments, ortho and meta substituents may comprise a hydrogen atom (H) or a halogen atom (such as F, Cl, Br, or I). In embodiments comprising a para substituent, it may comprise H, a halogen, or a hydroxyl group (—OH).

With further reference to FIG. 6, for norbornene 606, which may be viewed as a product of fusing a cyclopentane structure with a cyclopentene structure, positional numbering begins at fusion carbon 1 and increases around the ring starting with the olefin; the apical (bridging) carbon is numbered 7.

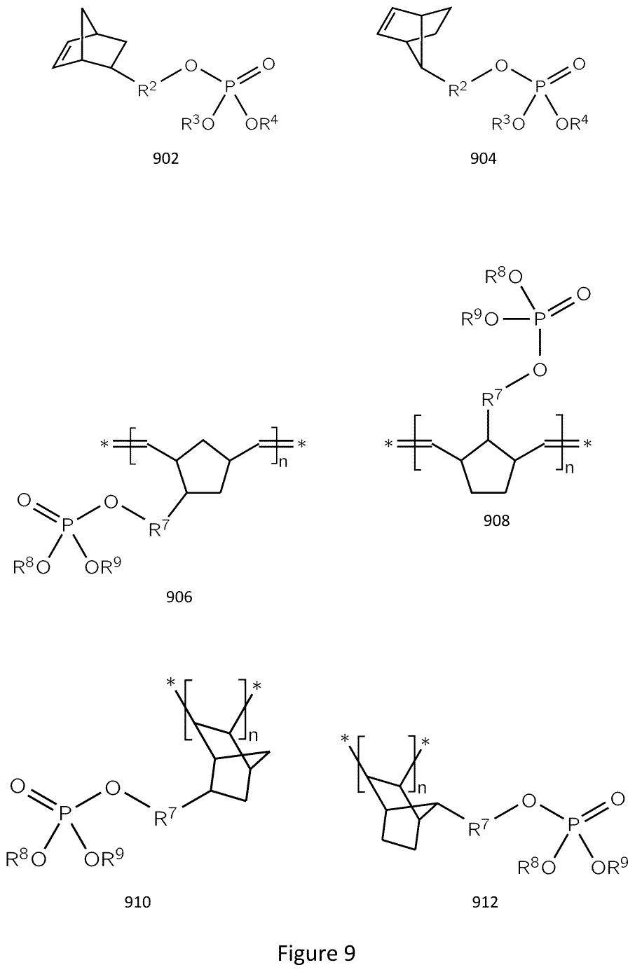

Embodiments of the generic monomer structure 502 may comprise norbornene-based monomers obtained (with reference to FIG. 7) by selecting the polymerizable unit R¹ to be derived from a norbornen-5-yl unit 704 or a norbornene-7-yl unit 706. The resulting norbornen-5-yl and norbornen-7-yl monomers 902 and 904 are illustrated in FIG. 9.

Because norbornene 606 is a strained bicyclic molecule, the monomers 902 and 904 may be especially amenable to ring-opening metathesis polymerization (ROMP) in the presence of a suitable catalyst, such as a transition metal-carbene (M=C—). In some embodiments, the transition metal-carbene may comprise a first-, second-, or third-generation Grubbs catalyst. Polymers formed by ring-opening metathesis polymerization from monomer 902 or 904 may be (respectively) norbornen-5-yl ROMP polymer 906 or norbornen-7-yl ROMP polymer 908, each having an unsaturated hydrocarbon backbone comprising carbon-carbon double bonds (C═C).

In other embodiments, vinylic addition (VA) of norbornenyl monomer 902 or 904 may respectively yield polymers such as norbornen-5-yl VA polymer 910 or norbornen-7-yl VA polymer 912. In still other embodiments, these and other polymerization mechanisms may compete, yielding still other norbornenyl polymers.

As mentioned above, and with further reference to FIGS. 4A and 4B, some embodiments of monomer photoresist formulation 40 may comprise a co-monomer 412, and some embodiments of polymer photoresist formulation 42 may comprise copolymer structure 418 or 420. In various embodiments of monomer photoresist formulation 40 comprising generic monomer structure 502, the co-monomer 412 may comprise the same polymerizable unit R¹ and side-chain connector R⁷ as generic monomer structure 502, but with the phosphate ester having been replaced by a different functionality. In these embodiments, a copolymer subsequently formed from the generic monomer structure 502 and the co-monomer 412 may have a consistent backbone structure but with variable structure in the side chains.

For example, in certain embodiments, the co-monomer 412 with DMMEP 506 may be ethyl methacrylate (replacing the phosphate ester with a hydrogen atom), hydroxyethyl methacrylate (replacing the phosphate ester with a hydroxyl group, —OH), or another methacrylate derivative with the same side-chain connector R⁷ as (and thus similar side-chain length to) DMMEP 506 (i.e., a 1,2-ethanediyl unit 708). In other embodiments, the co-monomer 412 may be chosen to endow the corresponding polymer 414 with improved physical properties (such as higher glass transition temperature, T_{g}), to improve solubility in coating or development solvents, to provide better adhesion to wafer substrates, or to tune the etch rate.

Similarly, in some embodiments of polymer photoresist formulation 42 comprising a copolymer, and with further reference to copolymer structures 510 and 512 in FIG. 5, the copolymer backbone unit R¹¹ may be the same as the backbone unit R⁶. For example, copolymerization of DMMEP 506 with methacrylate 604 (or with methacrylate derivatives) may form copolymers with a consistent backbone structure and side-chain variation.

That said, embodiments of monomer photoresist formulation 40 comprising a co-monomer 412 may include any suitable polymerizable monomer. In certain embodiments comprising co-monomers with polymerizable olefins, the co-monomer may be (with further reference to FIG. 6) an acrylate 602, a methacrylate 604, norbornene 606, styrene 608, 4-chlorostyrene 610, 4-hydroxystyrene 612, or the like.

In some embodiments, the co-monomer 412 may be an epoxy resin. In these embodiments, polymerization of the epoxy resin and subsequent crosslinking among phosphate esters of the monomer 402 during UV curing may endow a resulting polymer with advantageous etch resistance. In some such embodiments, the epoxy resin may comprise glycidyl methacrylate, a novolak resin, or another suitable epoxy resin.

As mentioned above, embodiments of the monomer photoresist formulation 40 may comprise the organic solvent 408. Similarly, some embodiments of the polymer photoresist formulation 42 may comprise the organic solvent 424. According to various embodiments, suitable solvents may be any organic solvent with a boiling point above 110° C. at 1 bar and with relative permittivity below 40 for at least one temperature below 35° C. In some embodiments, and with reference to FIG. 10, the organic solvent may be a conventional developer solvent such as 1-butanol 1002, isoamyl ether 1004, methyl isobutyl carbinol (4-methyl-2-pentanol or MIBC) 1006, propylene glycol methyl ether acetate 1008, or the like.

According to various embodiments, the suitability of a given organic solvent for use in the monomer photoresist formulation 40 or the polymer photoresist formulation 42 may be judged by considering a distance in Hansen solubility parameter space (HSP space) between the given organic solvent and a reference solvent, such as 1-butanol.

Hansen solubility parameter (HSPs) are a set of three parameters that may be used to estimate the solubility of materials, particularly polymers, in different solvents. The parameters are a dispersion parameter δD, which quantifies van der Waals (dispersion) forces present in all molecules; a polar parameter δP, which quantifies dipole-dipole interactions between polar molecules; and a hydrogen-bonding parameter δH, which quantifies the hydrogen-bonding interactions between molecules (if any).

The HSPs define a 3D space—Hansen space or HSP space—in which solvents and solutes can be mapped. A reference solvent may be represented by a point in HSP space with coordinate S°=(δD°, δP°, δH°); a sphere surrounding that point may represent the space of all solvents (or various combinations or admixtures of solvents and other materials) within a chosen non-negative “distance” of the reference. According to the basic chemical principle that “like dissolves like,” a reference point and a distance from that point in Hansen space may thus describe a set of solvents from which the organic solvent 408 (or the organic solvent 424) may be selected.

According to embodiments, reference HSP values may be those for 1-butanol 1002, S°_{1-butanol}=(δD°, δP°, δH°)=(16, 5.7, 15.8). The distance of a given other solvent from 1-butanol 1002 in Hansen space (the “Hansen distance”) may be calculated according to the equation

Distᵢ=\sqrt{(δD°−δDᵢ)²+(δP°−δPᵢ)²+(δH°−δHᵢ)²}, (Equation 1)

where Distᵢ represents the Hansen distance of the other solvent i (with Hansen parameters labeled thus) from the reference solvent.

According to embodiments, an individual organic solvent 408 or 424 may be selected if the Hansen distance of that solvent from 1-butanol 1002 is between 0 and 7, i.e., if the organic solvent 408 or 424 is within a sphere of radius 7 surrounding the reference point S°_{1-butanol} in Hansen space. A smaller distance may generally indicate greater similarity to the reference; as such, in some embodiments a Hansen distance range used to select an organic solvent 408 or 424 may be chosen between 0 and 6; between 0 and 5; between 0 and 4; and so on.

In some embodiments, a mixture of miscible solvents {i} may be considered for use in the monomer photoresist formulation 40 or the polymer photoresist formulation 42. In these embodiments, a weighted average of Hansen parameters may be used to characterize the mixture. For example, a Hansen dispersion parameter for a mixture may be calculated as δDₘᵢₓ=Σᵢ fᵢ δDᵢ, where fᵢ is the volume fraction of solvent i in the mixture, and the other parameters may be averaged according to similar formulas. The Hansen distance of the mixture from the reference may then be determined from Equation 1, i.e., by evaluating Distₘᵢₓ. According to these embodiments, a mixture of miscible solvents {i} may thus be selected if the Hansen distance of that mixture from 1-butanol 1002 is between 0 and 7, or (in other embodiments) between 0 and a smaller integer.

As mentioned above, and according to embodiments comprising a polymerization mixture, the monomer photoresist formulation 40 may comprise a photoinitiator 410. The photoinitiator 410 may be a Norrish type I photoinitiator forming radicals by cleavage (such as azobisisobutyronitrile, an α-hydroxyketone, or a phosphine oxide); a Norrish type II photoinitiator forming radicals by proton abstraction (such as camphorquinone, a benzophenone, or a thioxanthone); a cationic photoinitiator sharing features of both Norrish types (such as an iodonium or sulfonium salt); or any other suitable photoinitiator. In embodiments comprising Norrish type II or cationic photoinitiators, the monomer photoresist formulation 40 may additionally comprise a co-initiator (proton donor) such as an ether, amine, alcohol, or thiol.

According to various embodiments, the polymer photoresist formulation 42 comprises an acid generator 422. In some embodiments, the acid generator 422 may be a photoacid generator (PAG); as described above, some embodiments may instead comprise a thermal acid generator (TAG).

In certain embodiments comprising a photoacid generator, and as described below, the PAG may comprise a salt. In other embodiments, the PAG may be a nonionic photoacid generator such as a benzyl ester, an imino ester, a spiropyran, or a terarylene.

Cations and anions that may form suitable PAG salts are (respectively) illustrated in FIGS. 11A and 11B. With reference to FIG. 11A, and in various embodiments, a cation of the salt may comprise at least one aryl group 10 (a benzene ring substituted at any position), which may be written as Ar (as indicated by an equivalence sign 12), not to be confused with an argon atom.

PAG cations may comprise aryldiazonium 1102 (or equivalently 1104), diaryliodonium 1106, triarylsulfonium 1108, or triarylphosphonium 1110, with primes on the respective aryl groups indicate that distinct aryl functionalities may be present in some embodiments. PAG anions may comprise triflate 1112, perfluoro-1-butanesulfonate 1114, para-toluenesulfonate (or tosylate) 1116, or 2-(trifluoromethyl)benzenesulfonate 1118, according to embodiments.

In certain embodiments, the photoacid generator may comprise a triphenylsulfonium cation (triarylsulfonium 1108 with all three aryl groups selected to be a phenyl group, —C₆H₅) and any of the anions of FIG. 11B, i.e., the photoacid generator may be triphenylsulfonium triflate, triphenylsulfonium perfluoro-1-butanesulfonate, triphenylsulfonium tosylate, or 2-(trifluoromethyl)benzene-1-sulfonate. In another embodiment, the photoacid generator may be triphenylsulfonium 10-camphorsulfonate.

According to various embodiments, the polymer photoresist formulation 42 may further comprise a base quencher 426. The base quencher 426 may scavenge protons released by the acid generator 422 and thereby enable finer control over the number of protons available for crosslinking during the first baking process (as well as their mean free path before being scavenged). In other words, the base quencher 426 may help to tune the photospeed of the polymer photoresist formulation 42 and the sharpness of a pattern formed in a corresponding polymer coating 102 by exposure to the actinic radiation 104.

Any base quencher 426 soluble in the organic solvent 424 may be selected. In some embodiments, the base quencher 426 may comprise ammonium, an amine, an amide, a piperidine, a piperazine, a pyridine, a pyrimidine, or the like, with or without substitution. In certain embodiments, the base quencher 426 may comprise 1,8-diazabicyclo[5.4.0]undec-7-ene (DBU), 1-piperidineethanol (1-PE), tetrabutylammonium hydroxide (TBAH), or tetramethylammonium hydroxide (TMAH).

In various embodiments, the base quencher 426 may be a photodecomposable quencher (PDQ) that releases base or otherwise becomes activated by exposure to an actinic radiation. In some such embodiments further comprising a photoacid generator (PAG), the PDQ may be selected for compatibility with the PAG (e.g., sensitivity to the same or overlapping wavelengths of light). In other embodiments further comprising a PAG, the PDQ may be selected to be triggered by a wavelength of light well-separated from the wavelength that triggers the PAG, such that they may be activated separately (e.g., by distinct exposure steps).

In some embodiments, a photodecomposable quencher chosen as the base quencher 426 may be a nonionic PDQ such as a carbamate or an O-acyloxime. In other embodiments, the base quencher 426 may be an ionic PDQ such as triphenylsulfonium hydroxide or a quaternary ammonium salt comprising a complex anion (e.g., a borate). In embodiments comprising an ionic PDQ and an ionic PAG (i.e., a salt), the PDQ and the PAG may be chosen such that ion exchange is suppressed or has a limited effect on properties such as solubility of the PAG or PDQ, quantum yield of acid or base, and diffusion rate of acid or base.

Still other components may be part of the polymer photoresist formulation 42 in various embodiments. For example, the polymer photoresist formulation 42 may further comprise a plasticizer soluble in the organic solvent 424 and chosen to improve the mechanical properties of a corresponding polymer coating 102. In some embodiments, the plasticizer may comprise a phthalate, an isophthalate, or a terephthalate.

The process flows described with reference to FIGS. 1A-1F may represent various embodiments of a more general method of patterning a substrate, as illustrated by a flow chart in FIG. 12.

In box 1201, a polymer coating comprising phosphorus is formed over a substrate by a spin-on process. According to various embodiments, the phosphorus may be part of phosphate ester functional groups in the polymer coating. Next, in box 1202, the substrate is exposed to an actinic radiation through a photomask, thereby forming an exposed region and a masked region of the polymer coating. According to various embodiments, the actinic radiation may comprise ultraviolet (UV) radiation. Then, in box 1203, a first baking process is performed on the substrate to convert the exposed region of the polymer coating into a crosslinked region of the polymer coating. In some embodiments, these steps may result in a structure like that illustrated in FIG. 1C.

With further reference to FIG. 12 and the method charted therein, in box 1204, the substrate is rinsed with a solvent to remove portions of the masked region of the polymer coating, the removing forming a wet-developed region of the polymer coating. In some embodiments, the rinsing may be followed by performing a second baking process on the substrate to drive off residual solvent and to prepare the substrate for plasma treatment. Next, in box 1205, the substrate is loaded into a plasma processing chamber. Then, in box 1206, the substrate is exposed to a plasma to remove the wet-developed region of the polymer coating. In some embodiments, these steps may result in a structure like that illustrated in FIG. 1F.

Example embodiments of the invention are described below. Other embodiments can also be understood from the entirety of the specification as well as the claims filed herein.

Example 1. A photoresist formulation for coating substrates includes a monomer and an organic solvent. The monomer includes an olefin and a phosphate ester.

Example 2. The photoresist formulation of example 1, where the monomer includes a structure 502, where a polymerizable unit R¹ includes the olefin, a side-chain connector R² includes an organyl group, a first pendant group R³ of the phosphate ester includes a first hydrocarbyl group, a second pendant group R⁴ of the phosphate ester includes a second hydrocarbyl group, and a dashed bond between the polymerizable unit R¹ and the side-chain connector R² includes a single bond or a double bond.

Example 3. The photoresist formulation of example 2, where the polymerizable unit R¹ is a hydrocarbacrylate unit and the structure is structure 504, where a pendant group R⁵ of the hydrocarbacrylate unit includes a third hydrocarbyl group.

Example 4. The photoresist formulation of example 2, where the polymerizable unit R¹ is a styrenic unit and the structure is structure 802, structure 804, or structure 806, where a first ortho substituent R^{o}^{ₐ} is H or a halogen atom, a second ortho substituent R^{o}^{_{b}} is H or a halogen atom, a first meta substituent R^{m}^{ₐ} is H or a halogen atom, a second meta substituent R^{m}^{_{b}} is H or a halogen atom, and a para substituent R^{p} is H, a halogen atom, or a hydroxyl group.

Example 5. The photoresist formulation of example 2, where the polymerizable unit R¹ is a norbornenyl unit and the structure is structure 902 or structure 904.

Example 6. The photoresist formulation of one of examples 1 to 3, where the monomer is 2-[(dimethoxyphosphoryl)oxy]ethyl methacrylate (DMMEP).

Example 7. The photoresist formulation of one of examples 1 to 6, further including a co-monomer.

Example 8. The photoresist formulation of one of examples 1 to 7, where the co-monomer is an acrylate, a methacrylate, styrene, 4-chlorostyrene, 4-hydroxystyrene, or norbornene.

Example 9. The photoresist formulation of one of examples 1 to 8, where the organic solvent has a Hansen distance from 1-butanol in a range between 0 and 7.

Example 10. The photoresist formulation of one of examples 1 to 9, further including a photoinitiator.

Example 11. A photoresist formulation for coating substrates includes a polymer and an acid generator. The polymer includes a phosphate ester. The polymer and the acid generator are soluble in an organic solvent.

Example 12. The photoresist formulation of example 11, where the polymer includes a structure 508, where a backbone unit R⁶ includes a first organyl group, a side-chain connector R⁷ includes a second organyl group, a first pendant group R⁸ of the phosphate ester includes a first hydrocarbyl group, a second pendant group R⁹ of the phosphate ester includes a second hydrocarbyl group, dashed bonds to the backbone unit R⁶ include separately selected single or double bonds, and an integer n≥2.

Example 13. The photoresist formulation of example 12, where the backbone unit R⁶ is a hydrocarbacrylate unit and the structure is structure 514, where a pendant group R¹⁰ of the hydrocarbacrylate unit includes a third hydrocarbyl group.

Example 14. The photoresist formulation of example 12, where the backbone unit R⁶ is a styrenic unit and the structure is structure 808, structure 810, or structure 812, where a first ortho substituent R^{o}^{ₐ} is H or a halogen atom, a second ortho substituent R^{o}^{_{b}} is H or a halogen atom, a first meta substituent R^{m}^{ₐ} is H or a halogen atom, a second meta substituent R^{m}^{_{b}} is H or a halogen atom, and a para substituent R^{p} is H, a halogen atom, or a hydroxyl group.

Example 15. The photoresist formulation of example 12, where the backbone unit R⁶ is a norbornenyl unit and the structure is structure 906, structure 908, structure 910, or structure 912.

Example 16. The photoresist formulation of example 12, where the polymer further includes a first copolymer structure 510, a second copolymer structure 512, or both, where a copolymer backbone unit R¹¹ includes a third organyl group, a side chain R¹² includes a fourth organyl group, and dashed bonds to the copolymer backbone unit R¹¹ include single or double bonds.

Example 17. The photoresist formulation of one of examples 11 to 16, where the polymer includes poly(2-[(dimethoxyphosphoryl)oxy]ethyl methacrylate) (poly(DMMEP)).

Example 18. The photoresist formulation of one of examples 11 to 17, where the acid generator is a photoacid generator including an aryldiazonium salt, a diaryliodonium salt, a triarylphosphonium salt, or a triarylsulfonium salt.

Example 19. The photoresist formulation of one of examples 11 to 18, where the organic solvent has a Hansen distance from 1-butanol in a range between 0 and 7.

Example 20. The photoresist formulation of one of examples 11 to 19, further including a base quencher soluble in the organic solvent.

Example 21. A method of patterning a substrate includes forming a polymer coating over a substrate by a spin-on process, the polymer coating including phosphorus; exposing the substrate to an actinic radiation through a photomask to form an exposed region and a masked region of the polymer coating, where the actinic radiation includes ultraviolet (UV) radiation; performing a first baking process on the substrate to convert the exposed region of the polymer coating into a crosslinked region of the polymer coating; rinsing the substrate with a solvent to remove portions of the masked region of the polymer coating, the removing forming a wet-developed region of the polymer coating; loading the substrate into a plasma processing chamber; and exposing the substrate to a plasma to remove the wet-developed region of the polymer coating.

Example 22. The method of example 21, further including: after rinsing the substrate, performing a second baking process on the substrate.

Example 23. The method of one of examples 21 or 22, where the first baking process includes baking at a temperature between 100° C. and 200° C. for a period between 30 s and 2 min.

Example 24. The method of one of examples 21 to 23, where the actinic radiation is g-line radiation (436 nm visible light), h-line radiation (405 nm near UV), i-line radiation (365 nm UV), 284 nm deep UV, 193 nm deep UV, or 13.5 nm extreme UV.

Example 25. The method of one of examples 21 to 24, where the converting includes a transesterification reaction between molecules of the polymer coating.

While this invention has been described with reference to illustrative embodiments, this description is not intended to be construed in a limiting sense. Various modifications and combinations of the illustrative embodiments, e.g., of FIG. 1 and FIGS. 3-12, as well as other embodiments of the invention, will be apparent to persons skilled in the art upon reference to the description. It is therefore intended that the appended claims encompass any such modifications or embodiments.

What is claimed is:

1. A photoresist formulation for coating substrates, the photoresist formulation comprising:
a monomer comprising an olefin and a phosphate ester; and
an organic solvent.

2. The photoresist formulation of claim 1, wherein the monomer comprises a structure 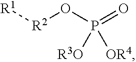
wherein a polymerizable unit R¹ comprises the olefin, a side-chain connector R² comprises an organyl group, a first pendant group R³ of the phosphate ester comprises a first hydrocarbyl group, a second pendant group R⁴ of the phosphate ester comprises a second hydrocarbyl group, and a dashed bond between the polymerizable unit R¹ and the side-chain connector R² comprises a single bond or a double bond.

3. The photoresist formulation of claim 2, wherein the polymerizable unit R¹ is a hydrocarbacrylate unit and the structure is 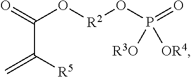
wherein a pendant group R⁵ of the hydrocarbacrylate unit comprises a third hydrocarbyl group.

4. The photoresist formulation of claim 2, wherein the polymerizable unit R¹ is a styrenic unit and the structure is 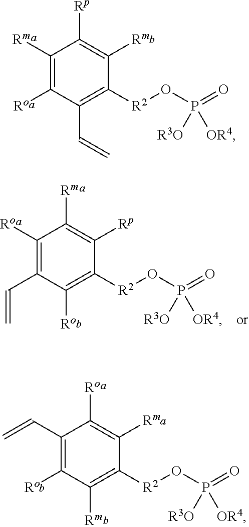
wherein a first ortho substituent R^{o}^{ₐ} is H or a halogen atom, a second ortho substituent R^{o}^{_{b}} is H or a halogen atom, a first meta substituent R^{m}^{ₐ} is H or a halogen atom, a second meta substituent R^{m}^{_{b}} is H or a halogen atom, and a para substituent R^{p} is H, a halogen atom, or a hydroxyl group.

5. The photoresist formulation of claim 2, wherein the polymerizable unit R¹ is a norbornenyl unit and the structure is

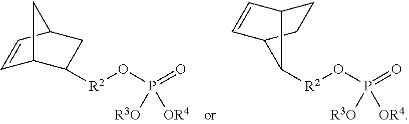

6. The photoresist formulation of claim 1, wherein the monomer is 2-[(dimethoxyphosphoryl)oxy]ethyl methacrylate (DMMEP).

7. The photoresist formulation of claim 1, further comprising a co-monomer, wherein the co-monomer is an acrylate, a methacrylate, styrene, 4-chlorostyrene, 4-hydroxystyrene, or norbornene.

8. The photoresist formulation of claim 1, wherein the organic solvent has a Hansen distance from 1-butanol in a range between 0 and 7.

9. A photoresist formulation for coating substrates, the photoresist formulation comprising:
a polymer comprising a phosphate ester; and
an acid generator, the polymer and the acid generator being soluble in an organic solvent.

10. The photoresist formulation of claim 9, wherein the polymer comprises a structure 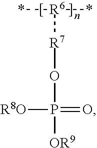
wherein a backbone unit R⁶ comprises a first organyl group, a side-chain connector R⁷ comprises a second organyl group, a first pendant group R⁸ of the phosphate ester comprises a first hydrocarbyl group, a second pendant group R⁹ of the phosphate ester comprises a second hydrocarbyl group, dashed bonds to the backbone unit R⁶ comprise separately selected single or double bonds, and an integer n≥2.

11. The photoresist formulation of claim 10, wherein the backbone unit R⁶ is a hydrocarbacrylate unit and the structure is 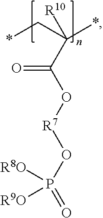
wherein a pendant group R¹⁰ of the hydrocarbacrylate unit comprises a third hydrocarbyl group.

12. The photoresist formulation of claim 10, wherein the backbone unit R⁶ is a styrenic unit and the structure is 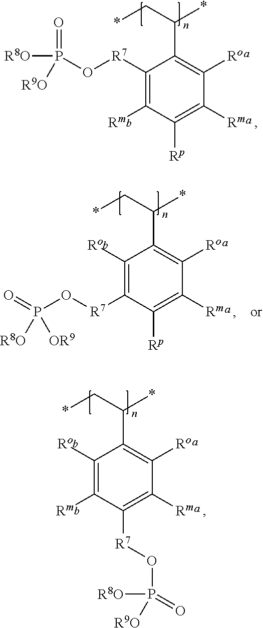
wherein a first ortho substituent R^{o}^{ₐ} is H or a halogen atom, a second ortho substituent R^{o}^{_{b}} is H or a halogen atom, a first meta substituent R^{m}^{ₐ} is H or a halogen atom, a second meta substituent R^{m}^{_{b}} is H or a halogen atom, and a para substituent R^{p} is H, a halogen atom, or a hydroxyl group.

13. The photoresist formulation of claim 10, wherein the backbone unit R⁶ is a norbornenyl unit and the structure is

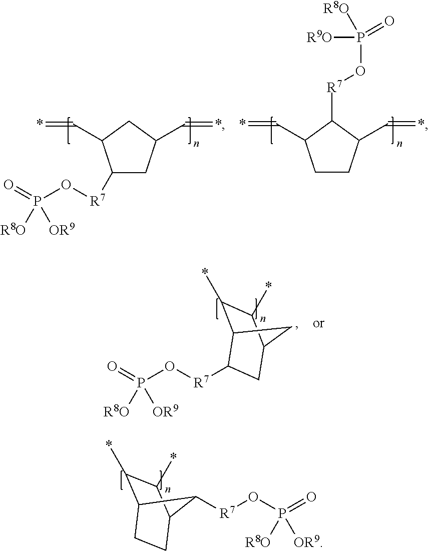

14. The photoresist formulation of claim 10, wherein the polymer further comprises a first copolymer structure 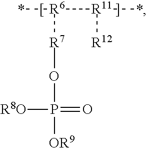
a second copolymer structure 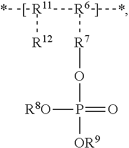
or both, wherein a copolymer backbone unit R¹¹ comprises a third organyl group, a side chain R¹² comprises a fourth organyl group, and dashed bonds to the copolymer backbone unit R¹¹ comprise single or double bonds.

15. The photoresist formulation of claim 9, wherein the polymer comprises poly(2-[(dimethoxyphosphoryl)oxy]ethyl methacrylate) (poly(DMMEP)).

16. The photoresist formulation of claim 9, wherein the acid generator is a photoacid generator comprising an aryldiazonium salt, a diaryliodonium salt, a triarylphosphonium salt, or a triarylsulfonium salt.

17. The photoresist formulation of claim 9, wherein the organic solvent has a Hansen distance from 1-butanol in a range between 0 and 7.

18. A method of patterning a substrate, the method comprising:
forming a polymer coating over a substrate by a spin-on process, the polymer coating comprising phosphorus;
exposing the substrate to an actinic radiation through a photomask to form an exposed region and a masked region of the polymer coating, wherein the actinic radiation comprises ultraviolet (UV) radiation;
performing a first baking process on the substrate to convert the exposed region of the polymer coating into a crosslinked region of the polymer coating;
rinsing the substrate with a solvent to remove portions of the masked region of the polymer coating, the removing forming a wet-developed region of the polymer coating;
loading the substrate into a plasma processing chamber; and
exposing the substrate to a plasma to remove the wet-developed region of the polymer coating.

19. The method of claim 18, wherein the first baking process comprises baking at a temperature between 100° C. and 200° C. for a period between 30 s and 2 min.

20. The method of claim 18, wherein the converting comprises a transesterification reaction between molecules of the polymer coating.
